(19) United States
(12) Patent Application Publication
(10) Pub. No.: US 2008/0242108 A1
(43) Pub. Date: Oct. 2, 2008

(54) Method for fabricating semiconductor device

(75) Inventors: Weng Chang, Hsinchu (TW); Fong-Yu Yen, Taoyuan (TW); Hun-Jan Tao, Hsinchu (TW); Mong-Song Liang, Hsinchu (TW)

Correspondence Address: BIRCH, STEWART, KOLASCH & BIRCH, LLP, P.O. BOX 747, FALLS CHURCH, VA, 22040-0747, US

(73) Assignee: TAIWAN SEMICONDUCTOR MANUFACTURING CO., LTD.

(21) Appl. No.: 11/730,551

(22) Filed: Apr. 2, 2007

(51) Int. Cl. H01L 21/46

(52) U.S. Cl. 438/763; 118/719; 257/E21.482

(57) ABSTRACT

A method for fabricating a semiconductor device is disclosed. The method includes providing a first chamber and a second chamber. The first chamber and the second chamber are connected by a pressure differential unit, for depositing a metallic film over a substrate in the first chamber, transferring the substrate to the second chamber via the pressure differential unit without exposing the substrate to the ambient environment, and depositing a silicon-containing film on the metallic film in the second chamber.

### BACKGROUND OF THE INVENTION

1. Field of the Invention

The invention relates to a method for fabricating a semiconductor device, and more particularly to a method for fabricating a metal electrode capable of eliminating surface oxidation due to the ambient environment.

2. Description of the Related Art

A metal oxide semiconductor field effect transistor (MOSFET) comprises a gate structure disposed between source and drain regions formed in a substrate. The gate structure typically comprises a gate electrode and a gate dielectric. The gate electrode is disposed over the gate dielectric to control a flow of charge carriers in a channel region formed between the drain and source regions under the gate dielectric. To reduce equivalent oxide thickness (EOT) at the 65 nm generation technology node and beyond, the gate dielectric may be formed from a material having a dielectric constant greater than 4. Materials for forming the gate electrode may comprise metal. Such dielectric materials are referred to as high-k materials in this specification. To maintain work function and reduce difficulty in post gate stack integration, a polysilicon layer is disposed on the metal to form a gate stack.

Typically, the metal layer of the gate stack is formed by physical vapor deposition (PVD) and the polysilicon layer of the gate stack is formed by chemical vapor deposition (CVD). In conventional MOSFET fabrication, the substrate must pass between various tools. Transporting the substrate between tools requires the removal of the substrate from the vacuum environment of one tool for transfer at ambient pressures to the vacuum environment of a second tool. In the ambient environment, the substrates are exposed to mechanical and chemical contaminants, such as particles, moisture and others, that may damage the gate electrode being fabricated and possibly form an undesired layer, such as, a native oxide layer.

As shown in FIG. 1A to 1C, a high-k dielectric layer 12 is disposed on a substrate 10 comprising isolation regions 11. In FIG. 1A, a metal gate layer 14 is deposited on the high-k dielectric layer 12 by a PVD tool. The metal gate layer 14 is sensitive to oxygen and moisture, which forms a native oxide when exposed to the ambient environment. In FIG. 1B, a metal oxide 15 is formed on the metal gate layer 14 due to the exposure of the metal gate layer 14 to the ambient environment prior to transfer of the substrate to a CVD tool for polysilicon deposition. As shown in FIG. 1C, the metal oxide 15 between the metal gate layer 14 and the polysilicon layer 16 greatly increases EOT and reduces the semiconductor device performance. In 65 nm technology node, inventor observed that native oxide is greatly increased and performance of transistor is seriously degraded. For instance, Capacitive Equivalent Thickness (CET) of native oxide formed on tantalum carbide is about 1.7 A if exposed to moisture for about 12 hours in semiconductor integrated circuit factory ambient. On the other hand, Capacitive Equivalent Thickness of native oxide formed on tantalum carbide will be about 9.3 A if exposed to moisture for about one week.

Thus, a method for fabricating a semiconductor device, capable of reducing EOT and enhancing device performance by eliminating exposure of the substrate to the ambient environment, is desirable.

### BRIEF SUMMARY OF THE INVENTION

The invention provides a method for fabricating a semiconductor device capable of reducing EOT and increasing device performance by preventing the formation of metal oxide resulting from exposure to the ambient.

An exemplary embodiment of a method for fabricating a semiconductor device, comprises: providing a semiconductor substrate; providing a first chamber and a second chamber connected by a pressure differential unit; depositing a metallic film over the substrate in the first chamber; transferring the substrate to the second chamber via the pressure differential unit without exposing the substrate to the ambient environment and depositing a silicon-containing film on the metallic film in the second chamber.

In one embodiment, the first chamber may be a CVD, PVD, LPCVD, PECVD or ALCVD chamber, and the second chamber may be a LPCVD or PECVD chamber. The first chamber and the second chamber can be different chambers of a single cluster tool system or chambers of different cluster tool systems. No metal oxide is formed between the metallic film and the silicon-containing film.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1A to 1C are schematic cross sectional views of a conventional process for fabricating a gate stack;

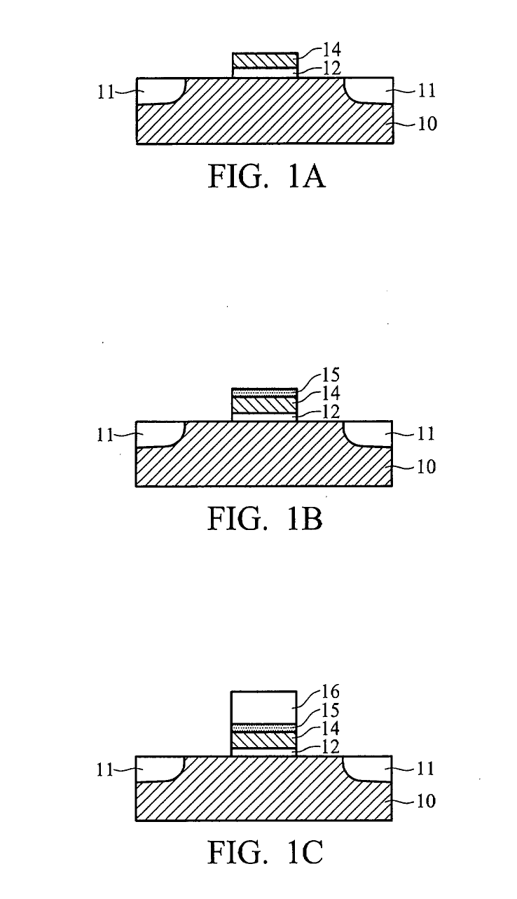

FIG. 2 is a schematic plan view of an equipment configuration of two cluster tool systems according to an embodiment of the invention;

FIG. 3 is a schematic plan view of an equipment configuration of a single cluster tool system according to another embodiment of the invention; and

FIGS. 4A to 4B schematic cross sectional views of a process of the invention for fabricating a gate stack.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The invention provides a method for fabricating a semiconductor device by in-situ deposition of a metallic film and a silicon-containing film to avoid formation of metal oxide. In one embodiment, the metallic film and the silicon-containing film are deposited in different chambers of a single cluster tool system. In another embodiment, the metallic film and the silicon-containing film are deposited in different chambers of two cluster tool systems. The metallic film can be deposited by a chemical vapor deposition (CVD), physical vapor deposition (PVD), low pressure chemical vapor deposition (LPCVD), plasma enhanced chemical vapor deposition (PECVD) or atomic layer deposition (ALCVD). The silicon-containing film can be deposited by a LPCVD or PECVD.

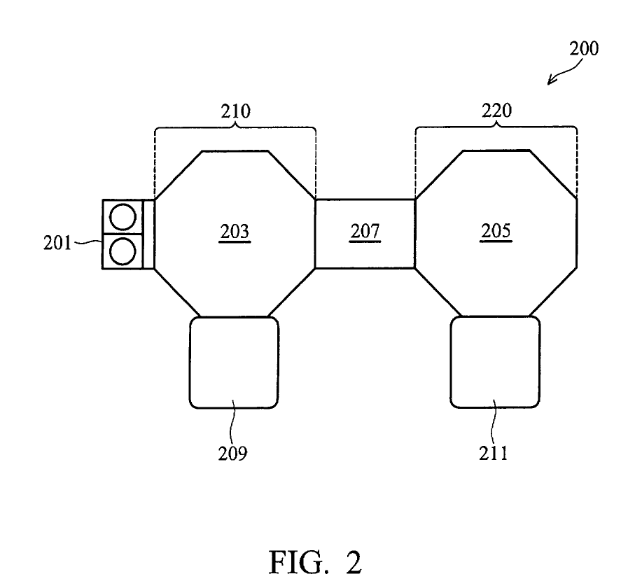

FIG. 2 is a schematic plan view of an equipment configuration 200 with two cluster tool systems for practicing the invention. The equipment configuration 200 comprises a load/unload unit 201, a first cluster tool system 210, a second cluster tool system 220 and a pressure differential unit 207 between the first and second cluster tool systems. The vacuum environment of pressure differential unit 207 to facilitate passage of a substrate between two cluster tool systems having different pressure.

The first cluster tool system 210 comprises a platform 203 and a chamber 209. The vacuum environment of the platform 203 is about 0.1˜20 torr for CVD process and 10E-6˜10E-8 torr for PVD process. Although in the figure, the first cluster tool system 210 only comprises one chamber, those skilled in the art will recognize the cluster tool system 210 can comprise more than one chamber. The chamber 209 can be a CVD, PVD, LPCVD, PECVD or ALCVD chamber for deposition of the metallic film, wherein a PVD chamber is preferred. The pressure of the chamber 209 is about 0.01˜20 mtorr for a PVD chamber and 0.1˜500 torr for a CVD chamber.

The second cluster tool system 220 comprises a platform 205 and a chamber 211. The vacuum environment of the platform 205 is about 0.1˜20 torr. Those skilled in the art will recognize that the cluster tool system 220 may comprise more than one chamber. The chamber 211 can be a LPCVD or PECVD chamber for deposition of the silicon-containing film, wherein a LPCVD chamber is preferred. The pressure of the chamber 211 is about 1˜400 torr.

The load/unload unit 201 loads a wafer on or unloads a wafer from, cluster tool system 210. The pressure of the load/unload unit 201 is required to facilitate passage of the substrate between the vacuum environment of the platforms 203 and the ambient environment outside of the load/unload unit 201. The platforms 203 and 205 transfer the wafer into or out of the chambers. In equipment configuration 200, the pressure differential unit 207 connects the chambers 209 and 211. Thus, the wafer is transferred from the chamber 209 to the chamber 211 via the pressure differential unit without exposing the wafer to the ambient environment. Additionally, the pressure differential unit 207 can comprise a load lock chamber (not shown).

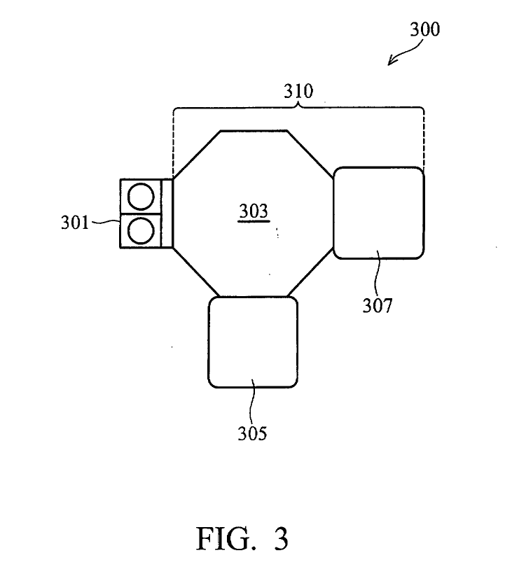

FIG. 3 is a schematic plan view of an equipment configuration 300 of a single cluster tool system for practicing the invention. The equipment configuration 300 comprises a load/unload unit 301 and a cluster tool system 310. The cluster tool system 310 comprises a chamber 305, a chamber 307 and a pressure differential unit 303 between the chambers 305 and 307. The vacuum environment of pressure differential unit 303 facilitates passage of a substrate between two chambers having different pressure.

The chamber 305 can be a CVD, PVD, LPCVD, PECVD or ALCVD chamber for deposition of the metallic film, wherein a PVD, CVD or ALD chamber are preferred. The pressure of the chamber 305 is about 0.01˜20 mtorr for a PVD chamber and 0.1˜500 torr for a CVD chamber. The chamber 307 can be a CVD or PECVD chamber for deposition of the silicon-containing film, wherein a CVD chamber is preferred. The pressure of the chamber 307 is about 1˜400 torr. Although in the figure, only the cluster tool system 310 only comprises two chambers, those skilled in the art will recognize the cluster tool system 310 can comprise more than two chambers.

The load/unload unit 301 loads a wafer to, or unloads a wafer from, the cluster tool system 310. The pressure of the load/unload unit 301 facilitates passage of the substrate between the vacuum environment of the pressure differential unit 303 and the substantially ambient environment of outside of the load/unload unit 301. In the equipment configuration 300, the pressure differential unit 303 connects the chamber 305 and 307, thus, the wafer is transferred from the chamber 305 to the chamber 307 via the pressure differential unit without exposing the wafer to the ambient environment. The pressure differential unit 303 can also be a platform for transferring the wafer into or out of the chambers and can comprise a load lock chamber (not shown).

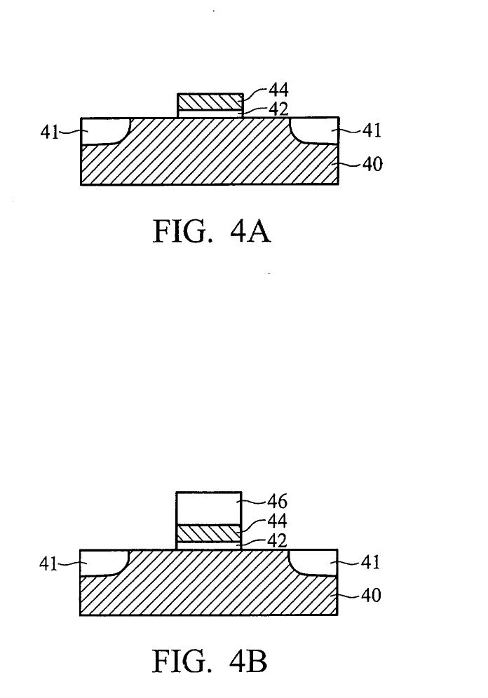

FIGS. 4A and 4B are cross sectional views of a process for fabricating a gate stack. As shown in FIG. 4A, a substrate 40 is provided, wherein isolation regions 41 such as shallow trench isolation (STI) regions are formed to define active areas. The material of the substrate may comprise single crystalline silicon or compound semiconductor. A gate dielectric layer 42 is disposed on the active area. The gate dielectric layer 42 can comprise conventional oxides or high-k materials having a dielectric constant greater than 4, such as HfO₂.

In one embodiment, the gate stack can be formed in the equipment configuration 200 of two cluster tool systems as shown in FIG. 2. A metallic film 44 can be deposited on the gate dielectric layer 42 by PVD in the chamber 209 and then transferred to the chamber 211 via the pressure differential unit 207 without exposing to the ambient environment. Accordingly, no metal oxide is formed on the metallic film 44 when transferred to the chamber 211 via the pressure differential unit 207. The material of the metallic film 44 may comprise metal nitride, metal carbide, metal, metal alloy or similar, such as TiN, TaN, TaC, TiC, Ti or Ta. The thickness of the metallic film is about 10 to 200 Å. As shown in FIG. 4B, a silicon-containing film 46 can be deposited on the metallic film 44 by CVD in the chamber 211. The material of the silicon-containing film can be amorphous silicon although polysilicon is preferred. Thickness of the silicon-containing film is about 500 to 2000 Å.

In another embodiment, the gate stack can be formed in the equipment configuration 300 of single cluster tool system as shown in FIG. 3. The metallic film 44 can be deposited on the gate dielectric layer 42 by PVD, CVD or ALD in the chamber 305, wherein PVD is preferred, and then transferred to the chamber 307 via the pressure differential unit 303 without exposure to the ambient environment. Thus, no metal oxide is formed on the metallic film 44. The silicon-containing film 46 can be deposited on the metallic film 44 by LPCVD in the chamber 307.

The metallic film 44 and the silicon-containing film 46 can be patterned into a gate electrode of a transistor subsequent to deposition over the substrate. Because the inventive method utilizes an equipment configuration of chambers connected by the pressure differential unit to deposit the metallic film and the silicon-containing film without exposing the substrate to the ambient environment, the formation of metal oxide between the metallic film and the silicon-containing film is avoided. The method can reduce EOT about 2 to 6 Å and reduce leakage current of very shallow source/drain junctions required by 65 nm and newer technologies to enhance the performance of semiconductor devices.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a semiconductor device, comprising:
providing a semiconductor substrate;
providing a first chamber and a second chamber, wherein the first chamber and the second chamber are connected by a pressure differential unit;
depositing a metallic film over the substrate in the first chamber;
transferring the substrate to the second chamber via the pressure differential unit without exposing the substrate to the ambient environment; and
depositing a silicon-containing film on the metallic film in the second chamber.

2. The method as claimed in claim 1, wherein the first chamber comprises CVD, PVD, LPCVD, PECVD or ALCVD chamber.

3. The method as claimed in claim 1, wherein the second chamber comprises LPCVD or PECVD chamber.

4. The method as claimed in claim 1, wherein the metallic film comprises metal nitride, metal carbide, metal or metal alloy.

5. The method as claimed in claim 1, wherein the metallic film comprises tantalum carbide.

6. The method as claimed in claim 1, wherein the metallic film has a thickness from 10 to 200 Å.

7. The method as claimed in claim 1, wherein the silicon-containing film comprises polysilicon or amorphous silicon.

8. The method as claimed in claim 1, wherein the silicon-containing film has a thickness from 500 to 2000 Å.

9. The method as claimed in claim 1, wherein the metallic film is sensitive to moisture to form a native oxide.

10. The method as claimed in claim 1, further comprising forming a high-k gate dielectric layer before forming the metallic film.

11. A cluster tool for fabricating a semiconductor device, comprising:
a first chamber for depositing metallic film; and
a second chamber for depositing silicon-containing film,
wherein the first chamber and the second chamber are connected by a pressure differential unit, wherein the pressure differential unit avoids exposing a semiconductor wafer to the ambient environment during transferring from the first chamber to the second chamber.

12. The cluster tool as claimed in claim 11, wherein the first chamber and the second chamber are different chambers of a single cluster tool system.

13. The cluster tool as claimed in claim 12, wherein the pressure differential unit comprises a transfer platform.

14. The cluster tool as claimed in claim 11, wherein the first chamber and the second chamber are chambers of different cluster tool systems.

15. The cluster tool as claimed in claim 14, wherein the pressure differential unit connects two transfer platforms of each of the cluster tool systems.

16. The cluster tool as claimed in claim 11, wherein the pressure differential unit comprises a load lock chamber.

17. The cluster tool as claimed in claim 11, wherein the metallic film comprises metal carbide.

18. The cluster tool as claimed in claim 11, wherein the first chamber comprises PVD chamber.

19. The cluster tool as claimed in claim 11, wherein the second chamber comprises LPCVD chamber.

20. The cluster tool as claimed in claim 11, wherein the silicon-containing film comprises polysilicon.
